(19) United States
(12) Patent Application Publication
(10) Pub. No.: US 2008/0236682 A1
(43) Pub. Date: Oct. 2, 2008

(54) System, methods and apparatuses for nanorobotics and microrobotics

(75) Inventor: Neal Solomon, Oakland, CA (US)

Correspondence Address: Neal Solomon, PO Box 21297, Oakland, CA, 94620, US

(73) Assignee: Solomon Research LLC, Oakland, CA (US)

(21) Appl. No.: 11/985,037

(22) Filed: Nov. 13, 2007

Related U.S. Application Data
(60) Provisional application No. 60/865,605, filed on Nov. 13, 2006.

(51) Int. Cl. H01L 21/02; B23Q 3/00; F15B 15/00

(52) U.S. Cl. 137/560; 438/689; 29/466; 977/902; 977/700; 257/E21.002

(57) ABSTRACT

A system for nanorobotics and microrobotics is disclosed with apparatuses for (a) assembly of joints, (b) connection of top-down nano structures, (c) micro-pump, (d) nano-balloon and (e) nanosail. The nano-balloon and nanosail apparatuses provide for nanorobotic mobility.

### CROSS-REFERENCES TO RELATED APPLICATIONS

The present application claims the benefit of priority under 35 U.S.C. § 119 from U.S. Provisional Patent Application Ser. No. 60/865,605, filed on Nov. 13, 2006, the disclosures of which are hereby incorporated by reference in their entirety for all purposes.

### FIELD OF THE INVENTION

The present invention pertains to the field of nanotechnology and nanorobotics. The system deals with epigenetic robotics applied to collectives of nanorobots. Specifically, the invention relates to nanoelectromechanical systems (NEMS) and microelectromechanical systems (MEMS), nanomechatronics and bionanomechatronics. The invention also deals with the coordination of collectives of nanorobots, synthetic nanorobotics and synthetic bionanorobotics, including synthetic assemblies of NEMS and nanorobots and synthetic nano-scale and micron-scale machine assembly processes. Applications of these systems and processes are made to nanoelectronics, bionanotechnology and nanomedicine.

### BACKGROUND OF THE INVENTION

To date, four waves, or generations, of nanotechnology have evolved. The first generation was comprised mainly of developments involving chemical composition, such as new nanomaterials. The second generation developed simple tubes and filaments by positioning atoms from the ground up with novel machinery. The third generation developed nanodevices that perform specific functions, such as nanoparticles for the delivery of chemicals. Finally, the fourth wave has developed self-assembling nanoentities by chemical means.

The present invention represents a fifth generation of self-organizing collectives of intelligent nanorobotics. Self-organizing processes are possible at the nano- and micron-level because of the convergence of nanoelectronics developments and nanomechatronics developments.

While the first four generations of nanotechnology have been developed by theoretical scientists and inventors, the fifth generation of nanotechnology has been largely open until now. The present invention fills the gaps in the literature and in the prior art involving nanorobotics.

Early twentieth century theoretical physicists discovered that the simplest atoms were measurable at the nanometer scale of one billionth of a meter. In 1959, in his lecture “Race to the Bottom,” the physicist Richard Feynman proposed a new science and technology to manipulate molecules at the nanoscale. In the 1970s Drexler's pioneering research into nanotechnology molecular-scale machinery provides a foundation for current research. In 1979, researchers at IBM developed scanning tunneling microscopy (STM) with which they manipulated atoms to spell the letters IBM. Also in the 1970s Ratner and his team at Northwestern developed the first nano-scale transistor-like device for nanoelectronics, which was developed into nanotransistors by researchers at the University of California at Berkeley in 1997. Researchers at Rice, Yale and Penn State were able to connect blocks of nanodevices and nanowires, while researchers at Hewlett Packard and UCLA were able to develop a computer memory system based on nano-assembly. Additionally, government researchers at NASA, NIST, DARPA and Naval Research have ongoing nanotechnology development projects, though these are mainly focused on nanoelectronics challenges. Finally, researchers at MIT, Cal Tech, USC, SUNY, Cornell, Maryland, Illinois and other universities in the U.S. have been joined by overseas researchers in developing novel nanotechnologies in order to meet Feynman's challenge.

Nanotech start-up ventures have sprung up to develop nanoscale crystals, to use as biological labels, for use in tagging proteins and nucleic acids (Quantum Dot) and to develop micro-scale arms and grippers by using MEMS to assemble manufacturing devices (Zyvex). Additionally, Nanosys, Nanometrics, Ultatech, Molecular Electronics, Applied Nanotech and Nanorex are ventures that have emerged to develop products in the nanotechnology market space. Until now, however, most of these businesses have focused on inorganic nanomaterials. Though a new generation of materials science has been aided by these earlier generations of nanotechnologies, the real breakthrough lies in identifying methods of developing intelligent systems at the nano-scale.

The two main models for building nanotechnology applications are the ground up method of building entities, on the one hand, and the bottom down method of shrinking photolithography techniques to the nanoscale. Both models present challenges for scientists.

In the case of the bottom up models, several specialized tools have been required. These include (a) atomic force microscopy (AFM), which uses electronics to measure the force exerted on a probe tip as it moves along a surface, (b) scanning tunneling microscopy (STM), which measures electrical current flowing between a scanning tip and a surface, (c) magnetic force microscopy (MFM), which uses a magnetic tip that scans a surface and (d) nanoscale synthesis (NSL), which constructs nanospheres.

In the case of the top down models, several methods and techniques have been developed, including (a) x-ray lithography, (b) ion beam lithography, (c) dip pen nanolithography (DPN), in which a “reservoir of ‘ink’ (atoms/molecules) is stored on top of the scanning probe tip, which is manipulated across the surface, leaving lines and patterns behind” (Ratner, 2003) and (d) micro-imprint lithography (MIL), which emulates a rubber stamp. Lithography techniques generally require the creation of a mask of a main model, which is then reproduced onto a substrate much like a semiconductor is manufactured. It is primarily through lithographic techniques that mass quantities of nanoentities can be created efficiently and cost-effectively.

The main patents obtained in the U.S. in the field of nanotechnology have focused on nanomaterials, MEMS, micro-pumps, micro-sensors, micro-voltaics, lithography, genetic microarray analysis and nano-drug delivery. Examples of these include a meso-microelectromechanical system package (U.S. Pat. No. 6,859,119), micro-opto-electro-mechanical systems (MOEMS) (US. Pat. No. 6,580,858), ion beam lithography system (U.S. Pat. No. 6,924,493), carbon nanotube sensors (U.S. Pat. No. 7,013,708) and microfabricated elastomeric valve and pump systems (U.S. Pat. Nos. 6,899,137 and 6,929,030). Finally, patents for a drug targeting system (U.S. Pat. No. 7,025,991) and for a design of artificial genes for use as controls in gene expression analytical system (U.S. Pat. No. 6,943,242), used for a DNA microarray, are applied to biotechnology. For the most part, these patents represent third and fourth generation nanotechnologies.

A new generation of nanotechnologies presents procedures for objects to interact with their environment and solve critical problems on the nano- and micron-scale. This generation of technology involves social intelligence and self-organization capabilities.

Biological analogies help to explain the performance of intelligent or self-organizing nanoentities. In the macro-scale environment, the behaviors of insects provides an important model for understanding how to develop models that emulate social intelligence in which chemical markers (pheromones) are used by individual entities to communicate a social goal. On the micro-scale, microbes and pathogens interoperate with the animal's immune system, in which battles either won or lost determine survival of the host. Other intracellular models show how proteins interact in order to perform a host of functions. At the level of DNA, RNA transcription processes are highly organized methods for developing cellular reproduction. These micromachinery processes and functions occur at the nanoscale and provide useful analogies for nanotechnologies.

In order to draw on these biological system analogies, complexity theory has been developed in recent years. Researchers associated with the Sante Fe Institute have developed a range of theoretical models to merge complexity theory and biologically-inspired processes, including genetic algorithms and collective behavior of economic agents.

Such a new nanotechnology requires distributed computation and communication techniques. It is, moreover, necessary for such a technology to adapt to feedback from its environment. The present invention presents a system in which these operations occur and specifies a range of important applications for electronics, medicine and numerous other areas. The main challenges to this advanced nanotechnology system lie in the discovery of solutions to the problems of limited information, computation, memory, communication, mobility and power.

Challenges

The development of a fifth generation of nanotechnologies faces several challenges. First, the manufacturing of nanoparts is difficult. Second, the assembly of nanoparts into functional devices is a major challenge. Fourth, the control and management of nanosystems is complex. Since physical properties operate differently at the nano-scale than at the macro-scale, we need to design systems that accommodate these unique physical forces.

The dozens of problems to identify include how to:
Build nanorobots
Connect nanodevices
Develop a nanorobotic power source
Develop nanorobotic computation
Develop specific nanorobotic functionality
Develop nanorobotic communication system(s)
Develop multi-functional nanorobotics
Activate nanorobotic functionality
Develop nanorobotic computer programming
Develop an external tracking procedure for a nanorobot
Develop an external activation of a nanorobot
Obtain environmental inputs via sensors

The Nanorobotic Environment

The nano domain, which is a billionth of a meter, is measured in millionths of a meter. A single oxygen atom is roughly a single nanometer across. A micron is a millionth of a meter. The width of a human hair is about 60,000 nanometers.

The present invention focuses on the synthetic development of objects that are in a middle (meso-nano) sphere somewhat between the atomic size (micro-nano) of simple atoms and the mega-nano domain of micron-sized objects. While it is true that scientists have built, from the ground up, that is, atom by atom, objects such as elegant geodesic nanotubes made of carbon atoms, objects in this domain are too small and too expensive to construct to be useful for an active intelligent system. In order to be useful, a nanorobotic system requires numerous and economical robots dependent on mass production techniques that must generally be considered from the perspective of a top down strategy, that is, by utilization of largely lithographic procedures.

The nanorobotic entities described herein generally consist of objects with dimensions from 100 nm to 1000 nm (1 micron) cubed, but can be smaller than 100 nm or larger than ten microns. This size is relatively large by nanotechnology standards, but is crucial in order to maintain functionality. Keep in mind that a white blood cell is comprised of about 100,000 molecules and fits into this meso-nano domain. The micron-scale space of inter-object interaction may be comprehended by analogy to a warehouse in which nanoscale objects interact. In order to be useful, nanorobots require complex apparatus that includes computation, communications, sensors, actuators, power source and specific functionality, all of which apparatus requires spatial extension. While this domain specification is larger than some of the atomic-scale research in nanotechnology, it is far smaller than most microelectronics.

While the larger meso-nano assemblies described herein possess a specific geometric dimensionality, the size dimensions of the domains in which they operate are also critical to consider. In these cases, each application has a different set of specifications. In the case of the human body, specific cells will have a dimensionality that is substantially larger than the complex molecular-size proteins that are constructed for interoperation within them.

Over time, however, it will be possible to make very small, useful micro-nano scale robots for use in intelligent systems. Thus, we may conceive of several generations of scale for these systems, the first being in the meso-nano domain.

### SUMMARY OF THE INVENTION

In order to be functional, nanorobots need to operate in groups. In order to be cost-efficient to develop large numbers of nanorobots, it is necessary to mass produce them. Nanorobots are mass-produced using various lithographic procedures whereby a design is developed computationally (with CAD), a mask created and the mask copied onto various materials. These materials include silicon, silicon germanium, gallium arsenide, gallium nitride, halfnium and indium phosphide. These nano production processes are typical of semiconductor production processes. However, there are notable differences between the two.

At a minimum, nanorobots consist of apparatuses that include a semiconductor for computation and memory, communications interface, motor, energy source, sensor(s) and actuator(s). The semiconductor, on the other hand, may consist of an application specific integrated circuit (ASIC), a simple microprocessor (including RISC), a field programmable gate array (FPGA), a zero instruction set computer (ZISC), an active storage device, a hybrid circuit or external memory. The semiconductor may include on-board digital-to-analogue and analogue-to-digital circuits. These basic components are necessary to process software with electronic circuits as well as communications signals. In time, it will be possible to integrate a quantum computer into the system. Because of the severe space constraints, the computation resources will be minimal. In general, these “brains” of the nanorobots are manufactured using nanoelectromechanical systems (NEMS) processes.

Aside from the electronic properties of the nanorobots, structural aspects consist of nanoscale parts designed and assembled into a larger assembly. Carbon nanotubes are useful as structural parts of nanorobots because of their strength and consistency, yet are difficult and expensive to build atom by atom. In general, lithographic-engineered parts are combined to create the housing for the nanorobots. Computer modeling is useful to develop integrated industrial designs for highly functional nanorobots. Multi-unit masks create thousands of nanorobotic components in a single mask.

The NEMS core is assembled within the nanorobotic structure. These procedures are performed using nanoproduction manufacturing techniques such as “stamping”, punching holes in parts and affixing fasteners. The thin film external shell of the nanorobots behaves like sheets of steel. In some cases, nanorobots consist of geodesic-configured parts built from the ground up using deposition approaches. These honeycombed grids are structured as half- or quarter-spheres that are attached with nanofilaments. These production and assembly processes are performed with efficient cellular factory techniques in a manufacturing facility in which multi-functional production machines interact. Because these processes are complex, nano-scale machines do not make other nano-scale machines, thereby making nanotechnology reproduction processes inefficient and impractical.

Another manufacturing technique for assembling nanorobots is to attach distinctively-cut parts that automatically “fit” or “slip” into position, similar to a docking process for binding proteins.

It is also possible to design nanorobots to change their shape or configuration when they are stimulated by internal or external processes such as heat or light. The geometric surfaces of nanorobots may be malleable in order to adapt to specific situations and extend their general usefulness. Such topological adaptation make these distinctive types of nanorobots multifunctional.

Main nanorobotic shapes may be spherical (geodesic sphere like a Bucky ball), cylindrical (submarine, torpedo or missile), elongated (hair) or complex (such as an “airplane” configuration). These basic structural forms are arranged with nanofilaments in complex ways in order to mimic the architecture of peptides and complex proteins. In order to provide protection from a hostile environment (such as heat or electrical current), some of these designs include a double-walled carbon nanotube as a strong foundation upon which to build. Except as building blocks for nanorobotic subsystems, parts built using bottom-up nanoproduction techniques are generally “blind”, “deaf” and “dumb” particles without autonomy, mobility or intelligence.

Highly complex nanorobots consist of an integrated semiconconductor with external nanorobotic structures comprised of multiple layers constructed from nanolithographic processes. These processes include electron beam fabrication, ion-beam fabrication, molecular-beam epitaxy, x-ray lithography, deep UV lithography, black copolymer lithography and nano-imprint lithography.

Innovations

The present system provides a series of advances over the state of the art.

The present invention elucidates a range of novel and useful solutions to these important challenges to develop an effective fifth-generation nanotechnology system with multiple important applications.

The present system establishes ways to build nanorobotic parts and to assemble them, including methods for self-assembly. The present invention provides connection methods for optimizing top-down mass production of nano-structures. The system also provides a cellular method for efficient nanofactory production processes.

Thanks to the use of electromechanical apparatuses, these nanorobotic entities have both mobility and autonomy yet are structured into collectives. In some cases, the nanorobotic structures themselves will adapt. In other cases, the communications apparatus is integrated into the nanorobotic structure.

### DESCRIPTION OF THE INVENTION

The construction of nanorobots and microrobots are challenges for nano-scale technology. The two main models for building nano structures are the top down (lithographic) and the bottom up. Bottom up methods are used to create nano structures by placing atoms into groupings using complex machines that result in production of a single nano-scale transistor in about an hour. In order to be useful and cost efficient, it is necessary to mass produce nanostructures. Consequently, the most practical way to build nanorobotic parts is to use top down lithographic methods which involve designing a complex architecture, creating a mask and using photographic copying techniques to shrink and reproduce the design. Computer modeling procedures, such as CAD and electronic design automation (EDA) are useful in designing these photolithographic nanorobot parts.

After the nanoscale parts are fabricated, they need to be assembled. The current invention provides several categories of apparatus and discloses methods for their combination and assembly. These categories of parts include a nanopin and a joint structure for connecting nanoscale components, a micro-pump and storage assembly with nanovalves, an inflatable nanoballoon and a nanosail device. The combination of these novel components represents a leap forward for nanotechnology capabilities.

(1) Nano-scale Cellular Factory Production Process with Multi-functionality

The main challenges in producing nano-scale assemblies by using mass-production techniques are making the individual parts and assembling the parts into usable nanostructures. Traditionally, the general way to assemble nanoparts has been to use “self-assembly” techniques in which nanoparticles are manipulated by the use of physical forces such as heat or electromagnetic forces. These primitive processes, however, have been limited to simple particles that lack computation capability and autonomy. Still, such simple self-assembly processes do seem compelling for their use of physical attractive forces.

The key in combining nanoparts is to develop a production process in the lab that assembles parts as a typical factory would assemble them. This mass-production factory assembly process relies upon the design of nanoparts that will be assembled in a straightforward way. For example, the fitting together of two nanoparts may be accomplished by stamping them together, snapping them together via a set of interlocking grooves or pinning them together. The present system enables the combination of nanoparts by using any of these procedures.

In combining different types of parts, a hybrid assembly is created that may include parts constructed from top down components and bottom up components. Similarly, it is possible to build assemblies using components from bottom up fabrication methods or from top down components. As an example, after a simple computer circuit is constructed by using lithographic procedures, it is placed inside a carbon nanotube constructed by bottom up methods. Similarly, carbon filaments constructed from bottom up approaches are placed into a housing constructed by top down methods. The parts are originally designed for further assembly with a view to fitting together and combining them. The more simply the parts fit together, the more likely they are to be mass produced rapidly and thus manufactured cost efficiently.

One way to mass assemble nanocomponents is to use grids that automatically combine hundreds of identical parts to hundreds of other parts. Numerous identical components are affixed to each position of the grid, then lowered onto another grid that holds many identical, complementary components. The parts then “snap” together, and the grids are (magnetically) oriented to release after the parts are assembled. It is thus possible to create thousands of completed assemblies by completing one main task.

In most modem factories, the assembly line factory production process has been replaced by cellular assembly processes in which multiple multifunctional machines efficiently fabricate or assemble a range of products. The present invention applies these cellular factory techniques to the nanotechnology field.

In the cellular factory, a combination of parts is made using a super-efficient scheduling system in which parts arrive at the site of assembly just in time. In the nano factory, parts are combined using specific machines that precisely identify, place and fit the components together. Groups of nanofabrication and nanoassembly machines work in concert to produce groups of working nanorobots. Raw materials are input into the machines, complex processes used to fabricate the parts and other machines used to assemble the parts into useful products.

While the mass production process uses specialized machinery to produce specific parts within a division of labor, the cellular production process uses multifunctional machines that are capable of assembling a range of nanodevices more efficiently. Cellular production is preferred because with nanoparts being extremely complex and difficult to engineer and manufacture, their assembly is relatively straightforward. In some cases, the nanorobots themselves are multifunctional and require sophisticated design, fabrication and assembly techniques.

(2) Detachable Adjustable Nanopin for Nanoassembly Joint

One of the challenges in assembling nanoscale parts is engineering ways to connect the parts. The present system presents a method to attach parts with the use of a detachable and adjustable pin comprised of carbon filament.

The nanopin holds together parts from sheets to connect geodesic apparatuses. In one example, a geodesic dome consisting of a nanotube part is conjoined to other geodesic parts or sheets by using the pin assembly system. The inspiration for the nanopin comes from molecular biology and the peptide chain that conjoins proteins.

The nanopin fits into a joint subassembly that holds two subassemblies into place. The pin is detachable and is held in place either by using a groove in the assembly where the nanopin locks in place or by bending the end(s) of the pin.

(3) Connection Method for Top-down Nanostructures

Nano-scale parts created by using top down methods may be connected by (a) sealing (fusing) the parts together, (b) seating and binding the parts together, (c) stamping the parts together and (d) pinning the parts together. The nanoparts created by top down procedures tend to be physically larger than those created by the bottom up methods. In this sense, it is practical to consider them as nanoscale “Lego's” that are assembled by fitting and locking them in place with pre-existing grooves. These connection methods are mechanical in nature.

Traditional approaches have used physical processes to combine nanoscale parts, including heat and magnetic forces. While these functional processes are useful at micro-nanoscales, they are less reliable at meso-nanoscales.

(4) Micropump and Storage Assembly with Nanovalve

The need for storage is critical in delivering chemicals in the nanosphere. The present invention develops a sub-micron scale storage facility that uses a micro-pump assembly system employing a nanovalve. The nanoscale valve fits into the input section of the pump and regulates the flow of chemicals into and out of the storage assembly. The storage assembly, which includes an insulated bladder reservoir, needs to be relatively large by nanoscale standards in order to be useful.

One illustrative use of a micro-storage assembly in practice is the storing of ATP to excite cells by activating their mitochondria on demand.

The nanovalve subassembly is critical for controlling the throughput of chemicals in the microstorage assembly. The nanovalve subassembly has sensors that identify chemical flow activity. The nanovalve subassembly uses intelligent systems logic capabilities that include computation resources in order to optimally regulate the flow of chemicals in the system.

The microstorage assembly may be used as part of a larger assembly of functional apparatus such as a diagnostic device that both identifies a cellular dysfunction and simultaneously proceeds to regulate the mechanism.

The microfluidic system may be used to clean other machines. The system may carry gas as well as liquid.

The nanovalve in the microstorage facility is dynamic, that is, it can move the flow of chemicals into and out of the chamber as demand warrants. Similarly, the micropump is asymmetric in facilitating chemical flows into or out of the microstorage chamber.

In a further embodiment of the system, the storage assembly consists of multiple reservoirs and a chain of multiple micropumps and nanovalve controllers. In this way, the processing of chemicals is performed by modulating the series of micropumps and nanovalves in a sequence of waves. The parallel activating of the system of multiple micropumps in the array creates a sophisticated chemical storage system at the micro- and nano-levels that exhibits cascade behaviors. This system is useful in interacting with complex environments such as hot computer systems, regulating biological systems or limiting the damage of security systems. The system is also useful in removing waste from molecular scale environments.

(5) Inflatable Nanoballoon Apparatus

The invention also includes the description of an inflatable nanoballoon apparatus that consists of “flexible” material for transforming its shape. The nanoballoon in its deflated form stores and moves more easily. However, when it is activated, the nanoballoon apparatus inflates to as many times greater in volume as its material permits. Once deflated, the nanoballoon is folded down to a compact size like a small parachute. Its characteristic deflatability allows the nanoballoon to fit into compact crevices and then activate.

The nanoballoon is activated for use in clearing debris from a constricted passage or to block an opening. In addition, the nanoballoon is used to filter chemicals at a particular biological site; depending on its material, it allows specific chemicals to pass through while capturing others. Nanoballoons may be used as storage facilities and are thus integrated into the microstorage facility described above. Finally, multiple nanoballoons work in sequence of an assembly in order to maximize effective functionality in a limited time.

The material of the nanoballoon may be hard or soft. If it is hard, the material behaves like a shield. The active process of the nanoballoon's external shield material is activated on demand, like an automobile airbag. Further, the consistency of the nanoballoon material changes in texture from a soft state to a hard state and back again. It is also possible to install a hard external shell in the same nanoballoon that has a soft interior skin. The shell acts as a cover over the device to protect the main apparatus. The hard outer shell obviously helps to protect the apparatus from hostile environmental degradation and is thus considered a defensive application.

The material of the nanoballoon also varies in mesh consistency and may, for example, have tiny holes in it, like the mesh lattice of a net, in order to perform specific functions such as filtering a particular class of chemical. In one embodiment, the nanoballoon material itself is comprised of transformable collectives of nanorobots that change their shape and consistency as the demand of the environment requires.

(6) Nanosail Apparatus

The present system also uses a nanosail apparatus which consists of a small piece of material connected to a main nanorobotic apparatus. The nanosail apparatus has several important functions. First, it is used to carry the nanorobot to particular locations using wind or biological currents. Second, the nanosail is used as a trap to block a chemical process. Third, the nanosail is used to block the opening of a nanostructure. Fourth, when the nanosail is opened it behaves as a filter. Fifth, the nanosail may have chemicals pumped along its apparatus in order to apply them to a particular location. In this case, the nanosail may be chemically doped before it is deployed and activated on demand. A series of nanosail apparatuses may also be used to accomplish a task in order to increase their effectiveness in a limited time.

The material of the nanosail is made of various substances, including plastics. The main idea is that the sail material should be light and, in most cases, rigid.

The nanosail apparatus is integrated into mechanisms that employ other apparatuses of the present system. For example the microstorage and micropump assembly may be deployed to a location by using the nanosail.

Reference to the remaining portions of the specification, including the drawings and claims, will realize other features and advantages of the present invention. Further features and advantages of the present invention, as well as the structure and operation of various embodiments of the present invention, are described in detail below with respect to accompanying drawings.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference for all purposes in their entirety.

### DESCRIPTION OF THE DRAWINGS

FIG. 1 is a block diagram of a nanorobot with an embedded integrated circuit.

FIG. 2 is a schematic diagram of a grid to stamp an array of nanorobotic components.

FIG. 3 is a diagram of a nanopin connector.

FIG. 4 is a diagram of a view of a nanorobot with nanopin connectors.

FIG. 5 is a schematic diagram of the male and female connection apparatuses of nanopins.

FIG. 6 is a schematic diagram of a nanoballoon device.

FIG. 7 is a schematic diagram of the three phases of a nanoballoon from inflation to deflation to reinflation.

FIG. 8 is a schematic diagram of an apparatus consisting of an array of several nanoballoons.

FIG. 9 is a schematic diagram of a micropump and a nanoballoon with a nanovalve apparatus.

FIG. 10 is a diagram of a micropump and a nanoballoon.

FIG. 11 is a diagram of a nanosail apparatus.

FIG. 12 is a diagram of a pressurized container expelling a collective of nanorobots.

### DETAILED DESCRIPTION OF THE DRAWINGS

Nanorobots come in different forms with different functionality as they are used in electronics, biochemical and biological domains. The specific functionality of each nanorobot derives from the intelligence conferred by the integrated circuit embedded in each nanorobot. With nano-scale production of integrated circuitry, nanorobots are organized to contain embedded semiconductor components. Though the drawings specify the architecture of nano-scale robot devices, references to the system also apply to micro-scale robot devices.

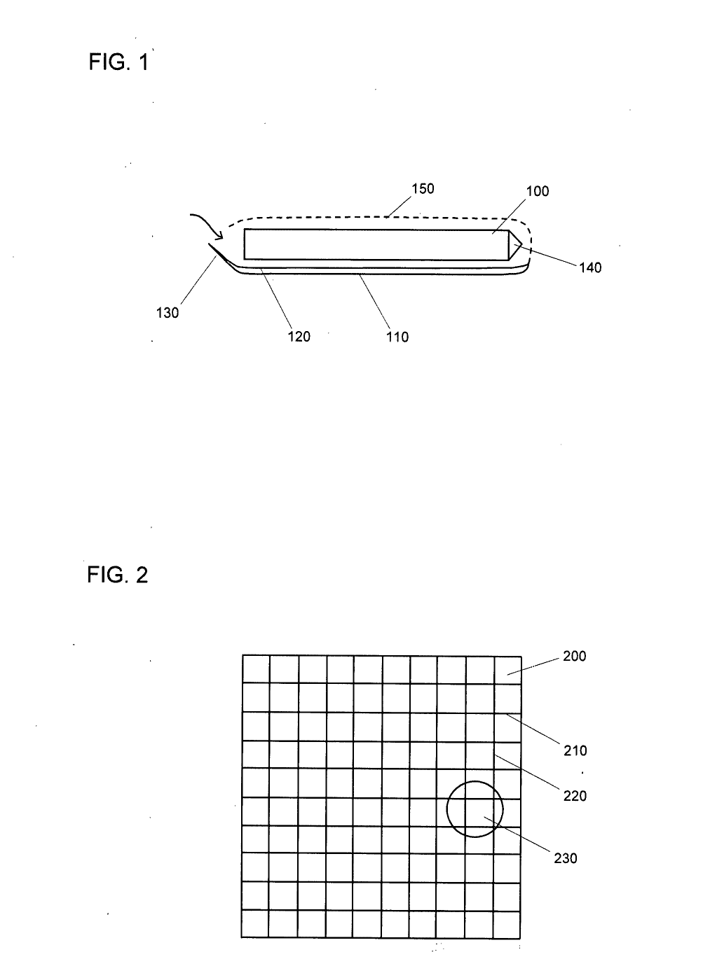

FIG. 1 illustrates a nanorobot (130) with an embedded integrated circuit (100). The IC is installed into the device by inserting it into the cavity (150). The nanorobot has an outer shell (110) and an inner shell (120) at the bottom of the device to prevent damage to the IC if the outer shell is pierced. Once the IC is embedded into the nanorobot, the top of the nanorobot folds down to secure the entry passage. This process allows the nanorobot to be manufactured separately from the IC devices. The apparatus will thus be able to accommodate multiple varied ICs with different configurations and capabilities.

In order to maintain efficiency in fabrication processes of nanorobots, the devices are manufactured in arrays. FIG. 2 shows a grid (200) of nanorobotic elements, the parts of which are created by stamping multiple units by using the grid. The vertical lines (220) and the horizontal lines (210) provide barriers for the square spaces (230) in which specific nanorobotic parts are created.

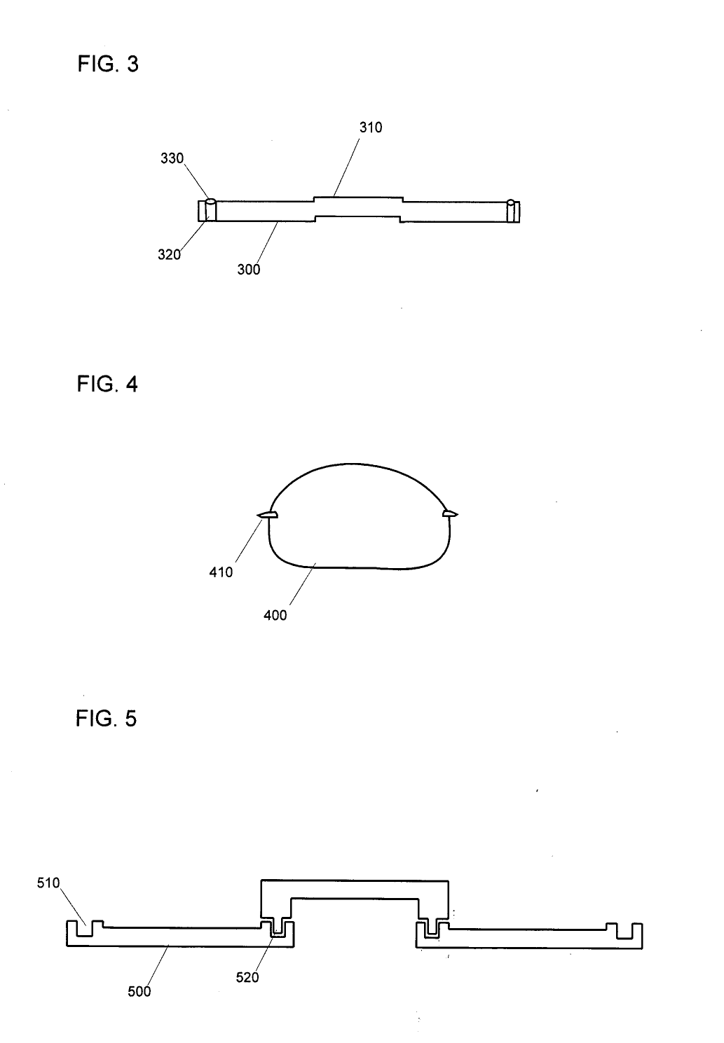

The nanorobotic parts are combined by using nanopins. FIGS. 3, 4 and 5 illustrate the nanopins. In FIG. 3, the nanopin connector (300) has a groove (310) that provides the alignment of the nanopins (330). FIG. 4 shows a nanorobot (400) with a nanopin (410) that connects to other nanorobotic assemblies. FIG. 5 shows the combination of several apparatuses. The nanopin male apparatus aligns a pin (520) to the female apparatus (500) in the groove (510). A derivative of this pin is the use of a two dimensional groove that attaches to a long two dimensional apparatus, which is another embodiment of the invention. The use of the nanopin illustrates a method to connect nanorobotic elements for specific functionality. By combining multiple nanorobots into assemblies, specific functionality is facilitated.

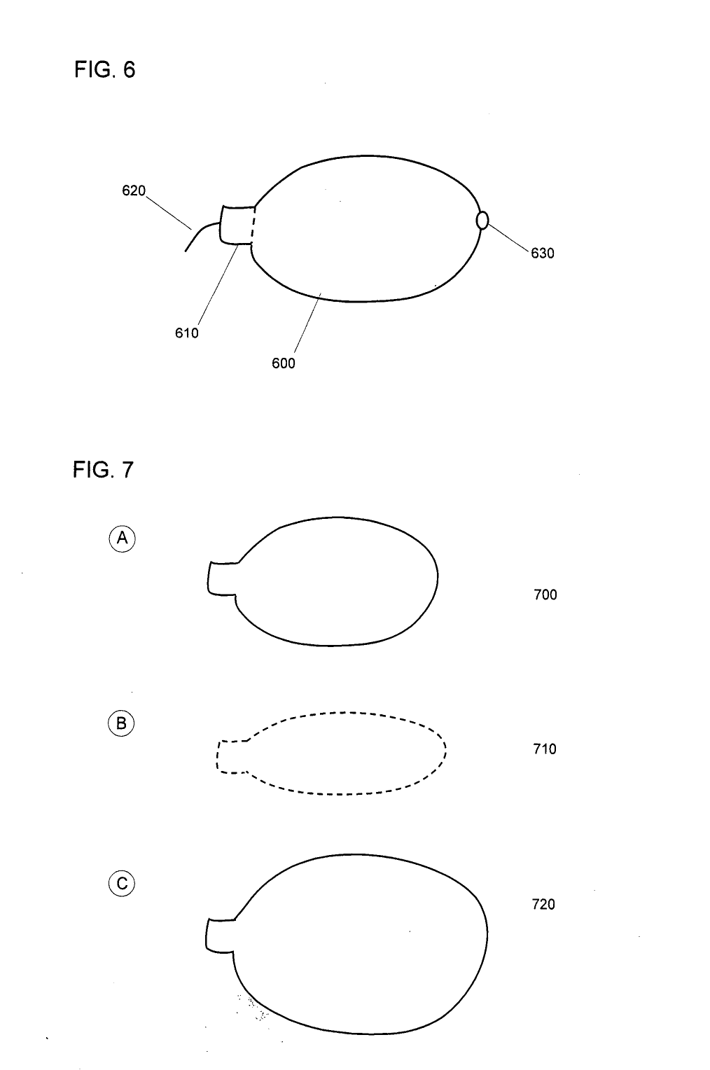

FIGS. 6, 7, 8, 9 and 10 illustrate the nanoballoon apparatus. Nanoballoons are useful (a) to carry cargo to specific locations, (b) to deflate and reinflate in order to penetrate specific spaces and (c) to perform specific mobile functionality. In FIG. 6, the nanoballoon (600) is show with a nanovalve (630) and electronic circuitry (610). A nanofilament (620) facilitates communications with the nanoballoon.

FIG. 7 shows the process of inflating (700) at (A), deflating (710) the device (B) and reinflating (720) the device (C) in a sequence of behaviors to carry cargo to a location that requires the apparatus to penetrate obstructions.

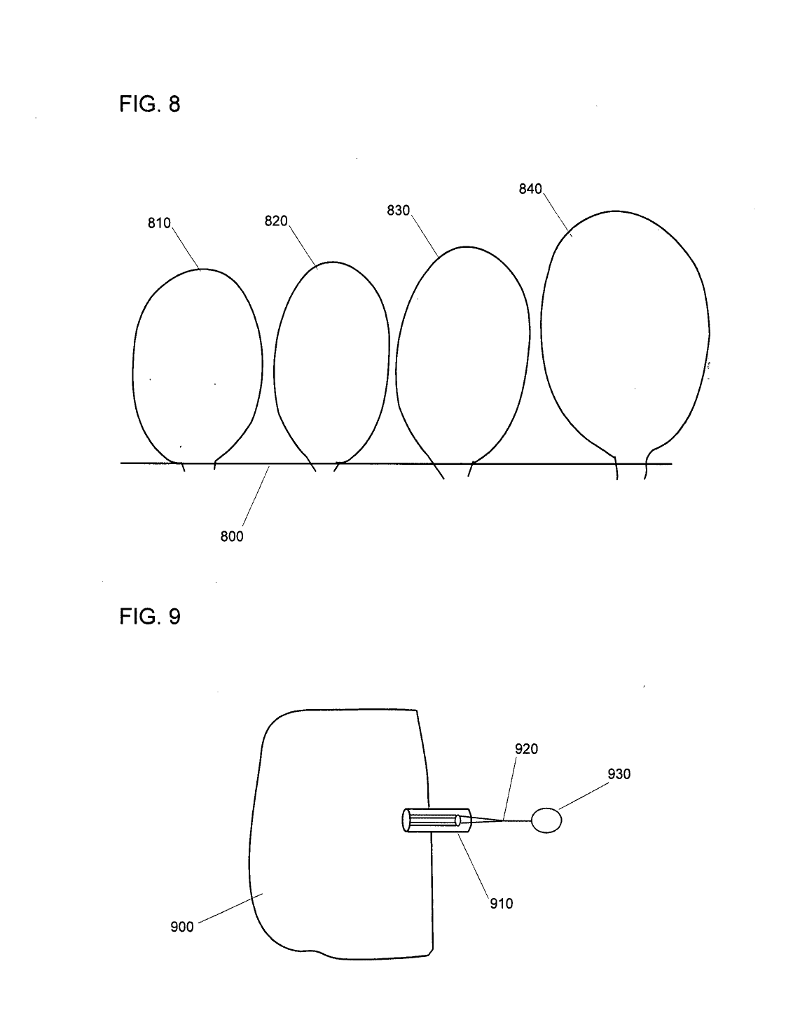

FIG. 8 shows four nanoballoons (810, 820, 830 and 840) aligned along an array and connected to a base station (800). This facility allows the storage and exchange of chemicals in a fixed apparatus arrangement.

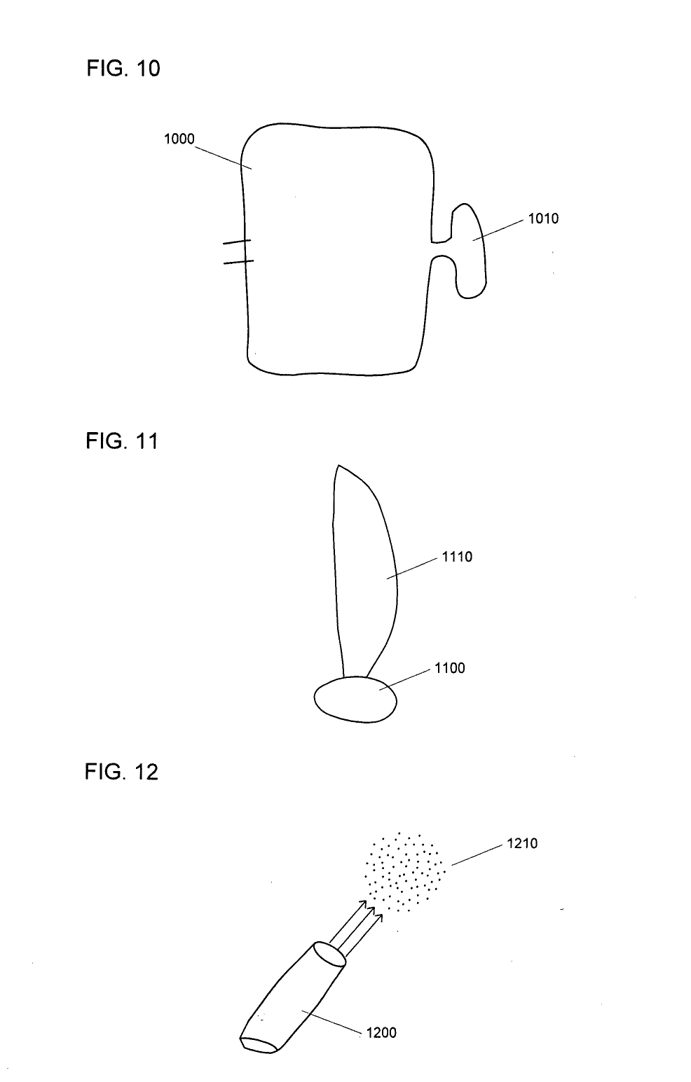

FIG. 9 shows a nanovalve apparatus (910) between a micropump (900) and a nanoballoon (930). The microneedle (920) fits between the nanovalve and the nanoballoon. The nanovalve apparatus contains components to control the load of chemicals to the nanoballoon. FIG. 10 shows the micropump (1000) and nanoballoon (1010) apparatuses connected together. The process of filling the nanoballoon begins when the nanoballoon lines up to the nanovalve on the micropump. The micropump fills up the nanoballoon to its limited capacity and detaches from the nanovalve assembly.

FIG. 11 illustrates a nanosail apparatus (1110) with a nanorobot (1100) affixed. This model of using a nanosail is a way to provide mobility to the devices. The device is able to control the directionality of the sail apparatus by adjusting the direction of the sail. This approach is particularly useful in self-enclosed environments in which the media provides chemical flows, such as biological systems.

FIG. 12 shows a pressurized chamber (1200) which discharges groups of nanorobots (1210). The pressurized capsule disperses the nanorobots at specific intervals.

The problem of nanorobotic mobility is solved with the present invention by describing methods of balloons, sails and pressurized chambers. In one embodiment, the system uses heat exchange as a method for mobility, in which the nanorobotic devices generally move from cold to hot. In some cases, a nanorobotic device laden with cargo will move from a hot to a cold position.

What is claimed is:

1. A system for constructing nanorobot devices, comprising:
a top-down lithographic fabrication technique;
wherein the nanorobot parts are fabricated in arrays;
wherein the nanorobot parts are combined by affixing the nanorobot devices on a grid and stamping the devices onto the frame of other devices;
wherein the nanorobot parts are stamped together at the edges of their frame by using a groove to connect the two layers;
wherein the nanorobot parts are combined in a matrix to combine numerous identical devices;
wherein the nanorobot parts are connected by using a nano-scale pin;
wherein the nano-scale pin is detachable;
wherein the nano-scale pin fits into a joint subassembly that holds two subassemblies into a fixed position.

2. A system for a nanoballoon apparatus, comprising:
a nanorobot device;
a nano-scale inflatable balloon structure;
a flexible material for a nano-scale balloon;
the nanoballoon is mobile;
wherein the nano-scale balloon inflates and deflates;
wherein the nano-scale balloon holds fluid cargo;
wherein the nano-scale balloon moves from location to location distributing its cargo;
wherein the nano-scale balloon clears debris from a constricted passage;
wherein the nano-scale balloon is structured to fit to a micro-scale pump;
wherein the nano-scale balloon moves to a restricted location in a deflated position and inflates to perform a function; and
wherein an array of nano-scale balloons are organized in a matrix configuration.

3. A system for a nanosail apparatus, comprising:
a nanorobot device;
a nano-scale inflatable sail structure;
a flexible material for a nano-scale sail;
the nanosail is mobile;
wherein the nano-scale sail inflates and deflates;
wherein the nano-scale sail moves from location to location;
wherein the nano-scale sail is used as a filter;
wherein the nano-scale sail is used as a trap to block a chemical process;
wherein the nano-scale sail is used to block the opening of a nano-scale structure;
wherein the nano-scale sail is chemically doped; and
wherein the nano-scale sail is made of polymers.
